(19) United States
(12) Patent Application Publication
(10) Pub. No.: US 2020/0388433 A1
(43) Pub. Date: Dec. 10, 2020

(54) Transformer Assemblies Including Electrically Conductive Shields And Lead Wires

(71) Applicant: Astec International Limited, Kwun Tong (HK)

(72) Inventors: Chi Wai Kevin WONG, Ma On Shan (HK); Kei Ho CHAN, Tseung Kwan O (HK)

(21) Appl. No.: 16/433,920

(22) Filed: Jun. 6, 2019

(51) Int. Cl. H01F 27/28; H01F 27/24; H01F 27/29; H01F 41/06; H02M 3/335; H05K 9/00

(52) U.S. Cl. CPC H01F 27/2885; H01F 27/24; H01F 27/29; H05K 9/0081; H01F 41/06; H02M 3/335; H01F 27/2823

(57) ABSTRACT

A transformer assembly includes a magnetic transformer core, at least one primary winding and at least one secondary winding. The at least one primary winding is wound about the magnetic transformer core, and the at least one secondary winding is wound about the magnetic transformer core. The transformer assembly also includes an electrically conductive shield and a lead wire. The electrically conductive shield is wrapped around the at least one primary winding and the at least one secondary winding to inhibit electromagnetic interference, and the lead wire is wrapped around at least a portion of the electrically conductive shield to mechanically and electrically couple the lead wire to the electrically conductive shield without solder.

### FIELD

The present disclosure relates to transformer assemblies including electrically conductive shields and lead wires.

### BACKGROUND

This section provides background information related to the present disclosure which is not necessarily prior art.

Transformer assemblies sometimes include a copper belly band wrapped around primary and secondary windings to reduce electromagnetic interference (EMI) generated by the primary and secondary windings. FIG. 1 illustrates a transformer assembly 100 including a copper belly band 108 wrapped around primary and secondary windings. The transformer assembly 100 also includes lead wires 112 and 114 coupled to the copper belly band 108 via solder 109 to secure and electrically connect the lead wires 112 and 114 to the copper belly band 108.

### SUMMARY

This section provides a general summary of the disclosure, and is not a comprehensive disclosure of its full scope or all of its features.

According to one aspect of the present disclosure, a transformer assembly includes a magnetic transformer core, at least one primary winding and at least one secondary winding. The at least one primary winding is wound about the magnetic transformer core, and the at least one secondary winding is wound about the magnetic transformer core. The transformer assembly also includes an electrically conductive shield and a lead wire. The electrically conductive shield is wrapped around the at least one primary winding and the at least one secondary winding to inhibit electromagnetic interference, and the lead wire is wrapped around at least a portion of the electrically conductive shield to mechanically and electrically couple the lead wire to the electrically conductive shield without solder.

According to another aspect of the present disclosure, a method of assembling a transformer including a magnetic transformer core is disclosed. The method includes winding a first wire about the magnetic transformer core to form at least one primary winding, winding a second wire about the magnetic transformer core to form at least one secondary winding, and wrapping an electrically conductive shield around the at least one primary winding and the at least one secondary winding to inhibit electromagnetic interference. The electrically conductive shield includes an inner surface facing towards the at least one primary winding and the at least one secondary winding, and an outer surface facing away from the at least one primary winding and the at least one secondary winding. The method also includes wrapping a lead wire around at least a portion of at least one of an outer surface of the electrically conductive shield, an outer surface of the at least one primary winding and an outer surface of the at least one secondary winding, to electrically couple the lead wire to the electrically conductive shield without solder and inhibit movement of the lead wire.

According to yet another aspect of the present disclosure, a transformer assembly includes a magnetic transformer core, at least one primary winding and at least one secondary winding. The at least one primary winding is wound about the magnetic transformer core, and the at least one secondary winding is wound about the magnetic transformer core. The transformer assembly also includes a lead wire and an electrically conductive shield. The lead wire is wrapped around at least a portion of the at least one primary winding and the at least one secondary winding, the electrically conductive shield is wrapped around the at least one primary winding and the at least one secondary winding to inhibit electromagnetic interference, and the electrically conductive shield is wrapped over the lead wire to electrically couple the lead wire to the electrically conductive shield without solder and inhibit movement of the lead wire.

Further aspects and areas of applicability will become apparent from the description provided herein. It should be understood that various aspects of this disclosure may be implemented individually or in combination with one or more other aspects. It should also be understood that the description and specific examples herein are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a front view of a transformer assembly including a lead wire soldered to a belly band, according to the prior art.

FIG. 2A is a front view of a transformer assembly including an electrically conductive shield.

FIG. 2B is a front view of the transformer assembly of FIG. 2A, including a lead wire wrapped around at least a portion of the electrically conductive shield, according to an example embodiment of the present disclosure.

FIG. 3A is a front view of a transformer assembly including a lead wire wrapped around at least a portion of the primary and secondary windings.

FIG. 3B is a front view of the transformer assembly of FIG. 3A, including an electrically conductive shield wrapped over the wound lead wire, according to another example embodiment of the present disclosure.

FIG. 4 is a circuit diagram of a transformer assembly including a lead wire electrically coupled with a voltage input terminal, according to a further example embodiment of the present disclosure.

FIG. 5 is a circuit diagram of a transformer assembly including a lead wire electrically coupled with a ground terminal, according to another example embodiment of the present disclosure.

FIGS. 6A and 6B are waveforms of example electromagnetic interference test scans at 100 Volts line and neutral for the transformer of FIG. 2B.

FIGS. 7A and 7B are waveforms of example electromagnetic interference test scans at 240 Volts line and neutral for the transformer of FIG. 2B.

Corresponding reference numerals indicate corresponding parts or features throughout the several views of the drawings.

### DETAILED DESCRIPTION

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

Example embodiments will now be described more fully with reference to the accompanying drawings.

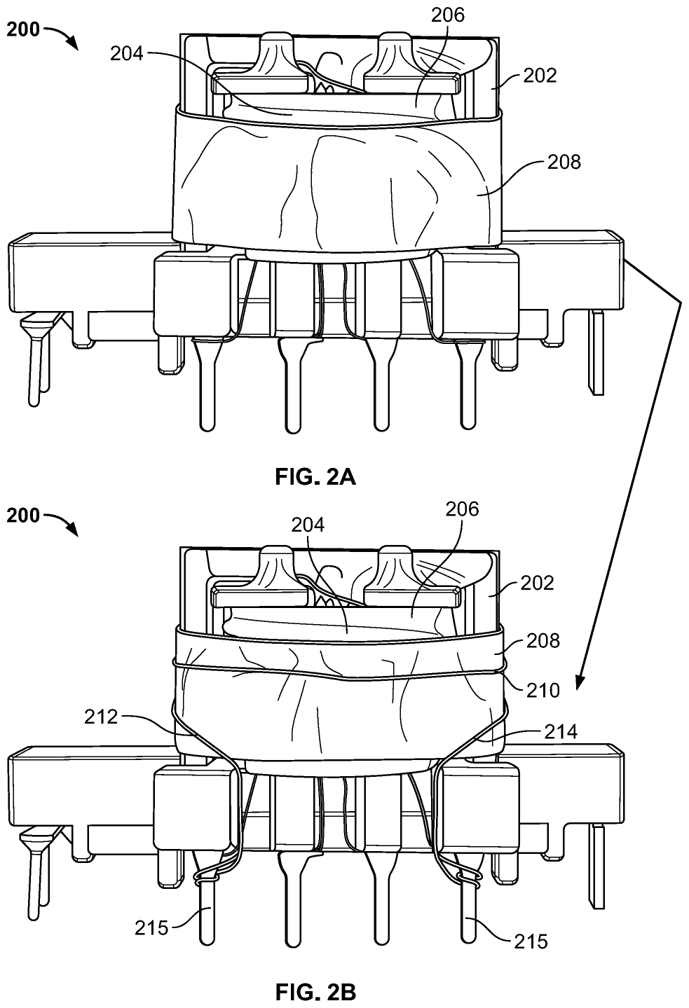

A transformer assembly according to one example embodiment of the present disclosure is illustrated in FIGS. 2A and 2B, and indicated generally by reference 200. FIG. 2A illustrates the transformer assembly 200 prior to wrapping a lead wire 210 around at least a portion of the electrically conductive shield 208, and FIG. 2B illustrates the transformer assembly 200 after the lead wire 210 has been wrapped around at least a portion of the electrically conductive shield 208.

The transformer assembly 200 includes a magnetic transformer core 202, a primary winding 204 and a secondary winding 206. The primary winding 204 is wound about the magnetic transformer core 202, and the secondary winding 206 is wound about the magnetic transformer core 202.

The transformer assembly 200 also includes an electrically conductive shield 208 (e.g., a copper belly band, etc.) and a lead wire 210. The electrically conductive shield 208 is wrapped around the primary winding 204 and the secondary winding 206 to inhibit electromagnetic interference.

As shown in FIG. 2B, the lead wire 210 is wrapped one and one half (e.g., 1.5, etc.) turns around the electrically conductive shield 208 to mechanically and electrically couple the lead wire 210 to the electrically conductive shield 208 without solder. As mentioned above, FIG. 2A illustrates the transformer assembly 200 before the lead wire 210 is wrapped around the electrically conductive shield, and FIG. 2B illustrates the transformer assembly 200 after the lead wire 210 is wrapped around the electrically conductive shield 208.

Wrapping the lead wire 210 around at least a portion of electrically conductive shield 208, such as the 1.5 turns illustrated in FIG. 2B, allows for establishing a non-solder electrical connection between the electrically conductive shield 208 and the lead wire 210.

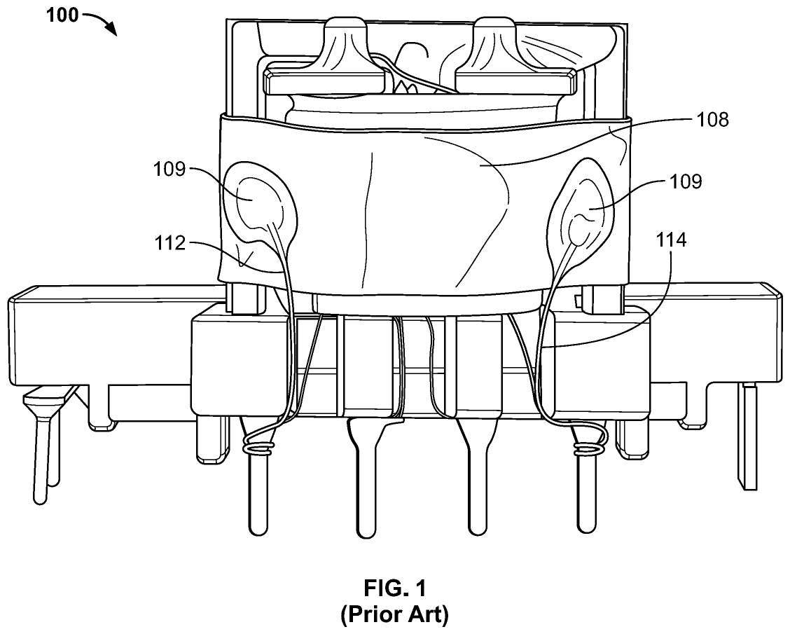

In contrast to wrapping the lead wire 210 around the electrically conductive shield 208 in the transformer assembly 200 illustrated in FIGS. 2A and 2B, previous approaches of using solder to connect the lead wire 110 and the copper belly band 108 as shown in FIG. 1 require extra manual processing or custom automated soldering machines adapted to only one type of transformer.

Also, when soldering the lead wire 110 to the copper belly band 108 as shown in FIG. 1, the solder must be applied to a transformer with completed windings, which creates a high risk that the solder ball will melt into the windings and create a high potential (hipot) failure.

Another approach of using conductive glue to join a lead wire and a copper belly band makes it difficult to control the quality of the glue application, and relies on only manual or semi-automated applicant techniques. Many glued transformer assemblies may be rejected for cosmetic reasons due to the liquid state of the glue before curing, and inconsistent amounts of more or less glue may be used in each transformer due to variations in operators' skill levels.

In contrast to the previous approaches of using solder or conductive glue to electrically couple a lead wire to a copper belly band, wrapping the lead wire 210 around the electrically conductive shield 208 in the transformer assembly 200 of FIG. 2B may allow for use of an automated winding machine (e.g., a multiple spindle automated winding machine), may eliminate solder balls and associated hipot failures, may increase productivity yields by eliminating inefficient manufacturing soldering processes and eliminating required customization and sophistication in production line automation for soldering, etc.

Wrapping the lead wire 210 around the electrically conductive shield 208 one and a half times may retain the lead wire 210 on the electrically conductive shield 208 (e.g., to mechanically connect the lead wire 210 and the electrically conductive shield 208), and create an electrical connection between the lead wire 210 and the electrically conductive shield 208, without using solder or conductive glue.

The lead wire 210 may then be connected to a voltage input terminal, a ground terminal, etc. of the transformer assembly 200 as described further below, to facilitate electromagnetic interference shielding of the transformer assembly 200 and its primary and secondary windings 204 and 206 by the electrically conductive shield 208.

For example, the electrically conductive shield 208 may include any material suitable for providing electromagnetic interference shielding to the transformer assembly 200 and its primary and secondary windings 204 and 206, such as copper, etc.

Each primary winding and secondary winding 204 and 206 may include one or more winding wires (e.g., electrically insulated copper wires, etc.), which may be wound in one or more coils (e.g., electrically insulated coils), etc. For example, each primary and secondary winding 204 and 206 may be insulated by electrical tape (or any other suitable insulator) to inhibit electrical connection between the electrically conductive shield 208 and the primary and secondary windings 204 and 206.

The primary and secondary windings 204 and 208 may include a radial outer surface, and the electrically conductive shield may be wrapped around at least a portion of the radial outer surface. In other embodiments, the primary and secondary windings 204 and 206 may have a rectangular shape, a triangular shape, or any other suitable shape for an outer surface of the primary and secondary windings 204 and 206.

The electrically conductive shield 208 may be wrapped to cover at least fifty percent of the radial outer surface of the primary and secondary windings 204 and 206, at least ninety percent of the radial outer surface of the primary and secondary windings 204 and 208, all of the radial outer surface of the primary and secondary windings 204 and 208, etc.

The electrically conductive shield 208 may be an electrically conductive tape material having a flexibility, thickness, etc. suitable for wrapping the electrically conductive shield 208 around the primary and secondary windings 204 and 208 of the transformer assembly 200, and may be considered as a transformer “belly band”.

For example, FIGS. 2A and 2B illustrate electrically conductive shield 208 wrapped to cover most but not all of a radial outer surface of the primary and secondary windings 204 and 206. The primary and secondary windings 204 and 206 are not clearly distinguished from one another in FIGS. 2A and 2B due to the covering by the electrically conductive shield 208, but the primary and secondary windings 204 and 206 may be wound in any suitable transformer arrangement such as the primary winding 204 positioned radially outwards from the secondary winding 206, the secondary winding 206 positioned radially outwards from the primary winding 204, sandwiched primary and secondary windings 204 and 206, etc.

The lead wire 210 may include any suitable wire for establishing an electrical connection between the electrically conductive shield 208 and one or more terminals to facilitate electromagnetic interference shielding by the electrically conductive shield 208, such as a tin-coated wire, etc.

The lead wire 210 may include two wire ends 212 and 214 for electrical connection to a voltage input terminal of the transformer assembly 200, a ground terminal of the transformer assembly 200, etc. For example, FIG. 2B illustrates the wire ends 212 and 214 coupled to transformer pins 215 of the transformer assembly 200. The transformer pins 215 may be connected to a ground potential, a voltage input, etc.

As shown in FIG. 2B, the wire ends 212 and 214 extend beyond opposite sides of an outer surface of the electrically conductive shield 208. For example, the lead wire 210 is wrapped around the electrically conductive shield 208 one and one half times so the wire ends 212 and 214 extend beyond the electrically conductive shield 208 at approximately opposite sides of the electrically conductive shield 208 to connect to the transformer pins 215 located on opposite sides of the transformer assembly. Although approximately 1.5 turns of the lead wire 210 are illustrated in FIG. 2B, the wire ends 212 and 214 may extend beyond the electrically conductive shield 208 at different sides when the lead wire is wound in a range between 1.1 to 1.9 times (or any multiple of 1.1 to 1.9), such as approximately 1.2 times, 1.3 times, 1.4 times, 1.6 times, 1.7 times, 1.8 times, etc.

In other embodiments, the lead wire may be wrapped around the electrically conductive shield more or less times. For example, the lead wire 210 may be wrapped less than one full turn around the electrically conductive shield 208 (e.g., around about half of the electrically conductive shield, etc.), and may be held in place contacting the electrically conductive shield 208 via the transformer pins 215. The amount of turns, or less than a full turn, may depend on a capability of an automatic winding machine, etc.

The lead wire 210 may be wrapped more than 1.5 turns around the electrically conductive shield 208, such as 2.5 turns, 3.5 turns, etc. Increasing the number of turns of the lead wire 210 may increase the strength of the mechanical and/or electrical coupling between the wire 210 and the electrically conductive shield 208. For example, increasing the number of turns of the lead wire 210 may mechanically connect the lead wire 210 to the electrically conductive shield 208 more securely compared to lower number(s) of turns.

In some embodiments, the wire ends 212 and 214 may extend beyond other portions of the electrically conductive shield. For example, the wire ends 212 and 214 may extend from locations of the electrically conductive shield that are not opposite one another. The wire ends 212 and 214 may connect to different transformer pins 215 as shown in FIG. 2B, may connect to the same transformer pin 215, etc.

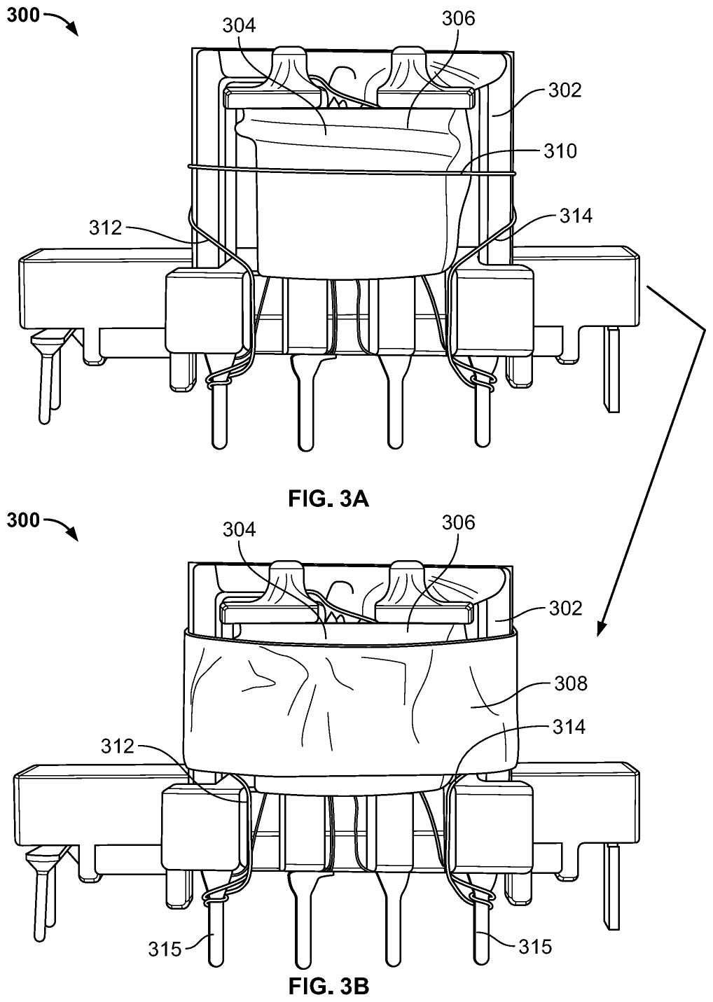

FIGS. 3A and 3B are front views of a transformer assembly 300 according to another example embodiment of the present disclosure. FIG. 3A illustrates the transformer assembly 300 prior to wrapping an electrically conductive shield 308 over the lead wire 310, and FIG. 3B illustrates the transformer assembly 300 after the electrically conductive shield 308 has been wrapped over the lead wire 310.

The transformer assembly 300 includes a magnetic transformer core 302, a primary winding 304 and a secondary winding 306. The primary winding 304 is wound about the magnetic transformer core 302, and the secondary winding 306 is wound about the magnetic transformer core 302.

The transformer assembly 300 also includes a lead wire 310 and an electrically conductive shield 308. As shown in FIG. 3A, the lead wire 310 is wrapped around at least a portion of the primary winding 304 and the secondary winding 306. As shown in FIG. 3B, the electrically conductive shield 308 is wrapped around the primary winding 304 and the secondary winding 306 to inhibit electromagnetic interference. The electrically conductive shield 308 is also wrapped over the lead wire 310 to electrically couple the lead wire 310 to the electrically conductive shield 308 without solder and inhibit movement of the lead wire 310.

As compared to the transformer assembly 200 of FIG. 2B where the lead wire 210 is wrapped over the electrically conductive shield 208, in the transformer assembly 300 the electrically conductive shield 308 is wrapped over the lead wire 310. Therefore, the lead wire 210 extends around (e.g., along, etc.) an outer surface of the electrically conductive shield 208 in the transformer assembly 200 of FIG. 2B, while the lead wire 310 extends around an outer radial surface of the primary winding 304 and the secondary winding 306 (and an inner surface of the electrically conductive shield 308) in the transformer assembly 300 of FIG. 3B.

Wrapping the electrically conductive shield 308 over the lead wire 310 may hold the lead wire 310 in place, with only the wire ends 312 and 314 of the lead wire 310 extending out from under the electrically conductive shield 308. The wire ends 312 and 314 may be coupled to create an electrical connection between the electrically conductive shield 308 and one or more transformer pins 315 (e.g., voltage input terminals, ground input terminals, etc.), to facilitate electromagnetic interference shielding by the electrically conductive shield 308.

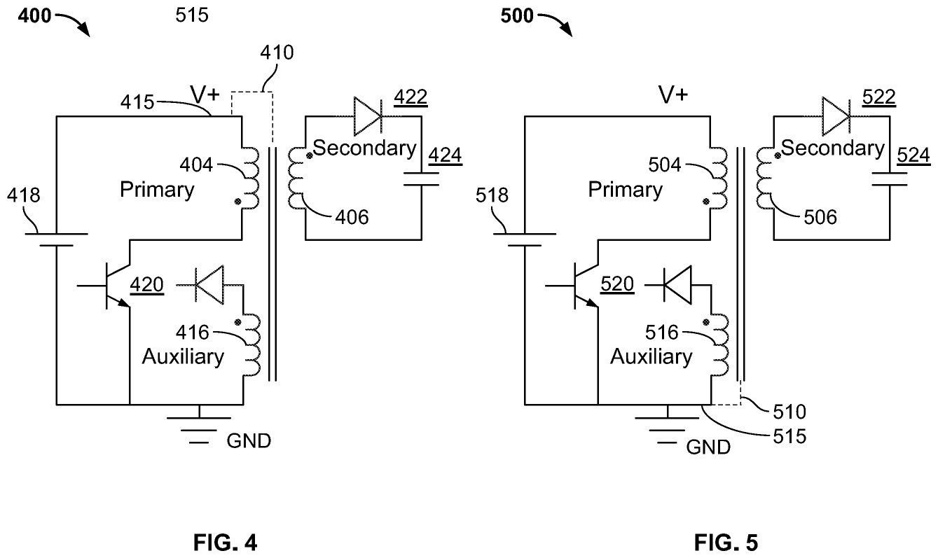

FIG. 4 is a wiring diagram illustrating connection of a lead wire 410 to a voltage input terminal V+(e.g., a positive bulk voltage, etc.) of a transformer assembly 400. The transformer assembly 400 includes a primary winding 404, a secondary winding 406 and an auxiliary winding 416. The lead wire 410 may be considered as electrically connected with the primary winding 404.

The lead wire 410 connects an electrically conductive shield (not shown) to the voltage input terminal V+(e.g., a voltage input pin 415) to facilitate electromagnetic interference shielding by the electrically conductive shield. For example, connecting the electrically conductive shield to the voltage input terminal V+ via the lead wire 410 may improve ability of the electrically conductive shield to inhibit noise generated by the primary and secondary windings 404 and 406, etc.

The transformer assemblies described herein may be used in any suitable application, such as a switched-mode power supply, components/assemblies/modules that require copper or other metal shielding, other applications that need to connect an EMI shield to a voltage input terminal, a ground/earth pin, etc.

FIG. 4 illustrates an example switched-mode power supply including the transformer assembly 400. The switched-mode power supply includes a voltage input terminal V+ for receiving power from a power source 418, a switch 420 for controlling current through the primary winding 404, and a diode 422 for selectively supplying current to a load 424.

The switched-mode power supply illustrated in FIG. 4 may be considered as a flyback converter, and may include additional components not shown in FIG. 4. In other embodiments, any other suitable power converter components, connections, topologies, etc. may be used. For example, transformer assemblies described herein may be especially suited for power conversion topologies requiring higher power density, less printed circuit board (PCB) space due to radiated EMI concerns, etc.

FIG. 5 is a wiring diagram illustrating connection of a lead wire 510 to a ground/earth potential terminal GND (e.g., a ground pin 515) of a transformer assembly 500. The transformer assembly 500 includes a primary winding 504, a secondary winding 506 and an auxiliary winding 516.

The lead wire 510 connects an electrically conductive shield (not shown) to the ground/earth potential terminal GND to facilitate electromagnetic interference shielding by the electrically conductive shield. For example, connecting the electrically conductive shield to the ground/earth potential terminal GND via the lead wire 510 may improve ability of the electrically conductive shield to inhibit noise generated by the primary and secondary windings 504 and 506, etc.

FIG. 5 illustrates an example switched-mode power supply including the transformer assembly 500. The switched-mode power supply includes a voltage input terminal V+ for receiving power from a power source 518, a switch 520 for controlling current through the primary winding 504, and a diode 522 for selectively supplying current to a load 524.

The input terminals V+ and the ground/earth potential terminals GND may include any suitable connector, terminal, wire, conductive trace, etc. for receiving a power from a voltage source, for establishing an electrical connection with an earth ground potential, etc.

As shown in FIGS. 4 and 5, the electrically conductive shield may be connected to a voltage input connection, a ground/earth connection, etc., as these connections may provide a relatively stable, steady, etc. voltage level for the transformer assembly.

Connecting the electrically conductive shield to a voltage input connection, a ground/earth connection, etc. may depend on the application of the transformer assembly. For example, in some mobile chargers the electrically conductive shield may be connected to a bulk V+ input, in some general power supplies the electrically conductive shield may be connected to ground/earth, etc.

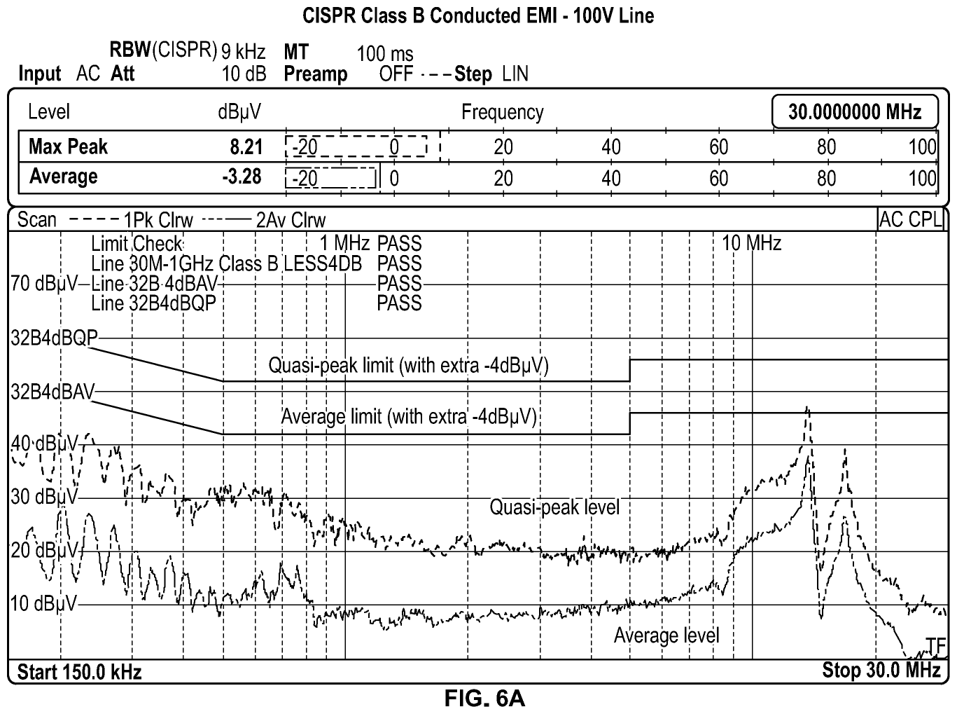

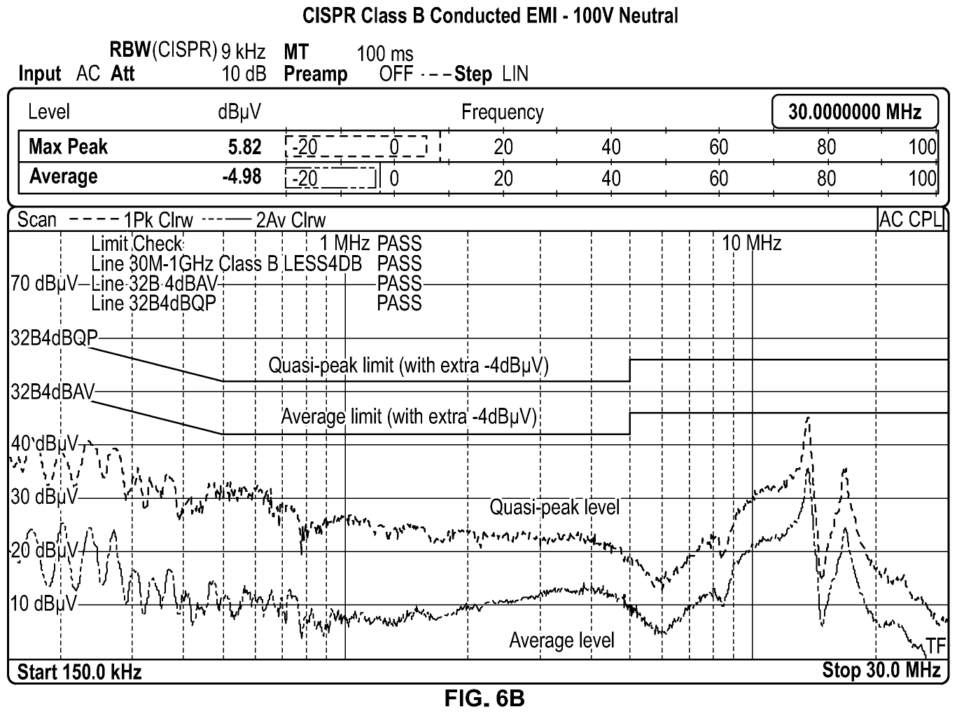

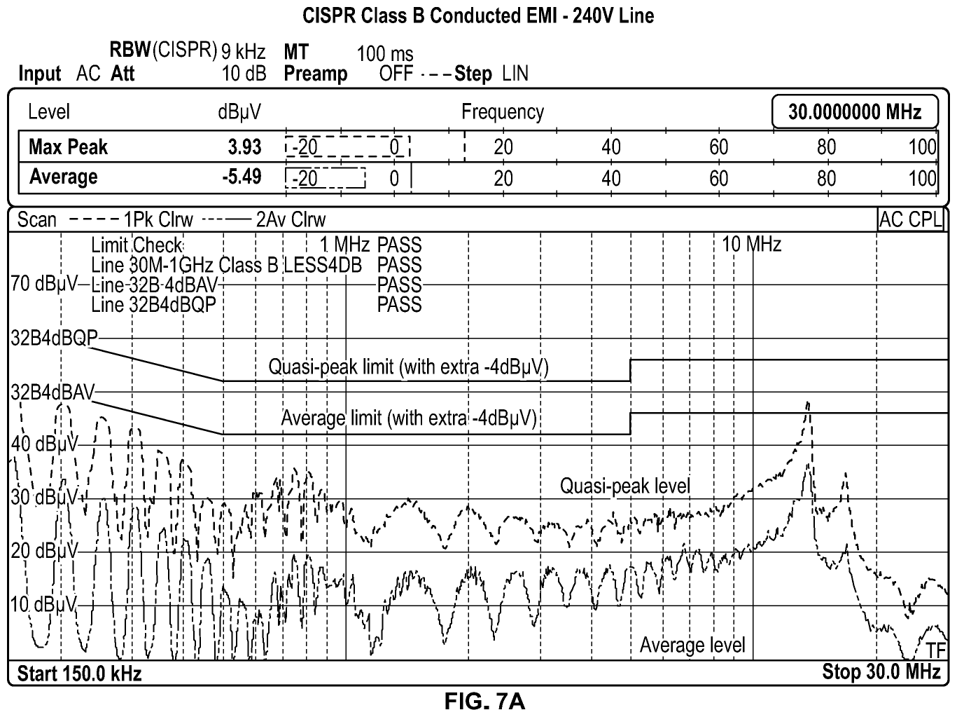

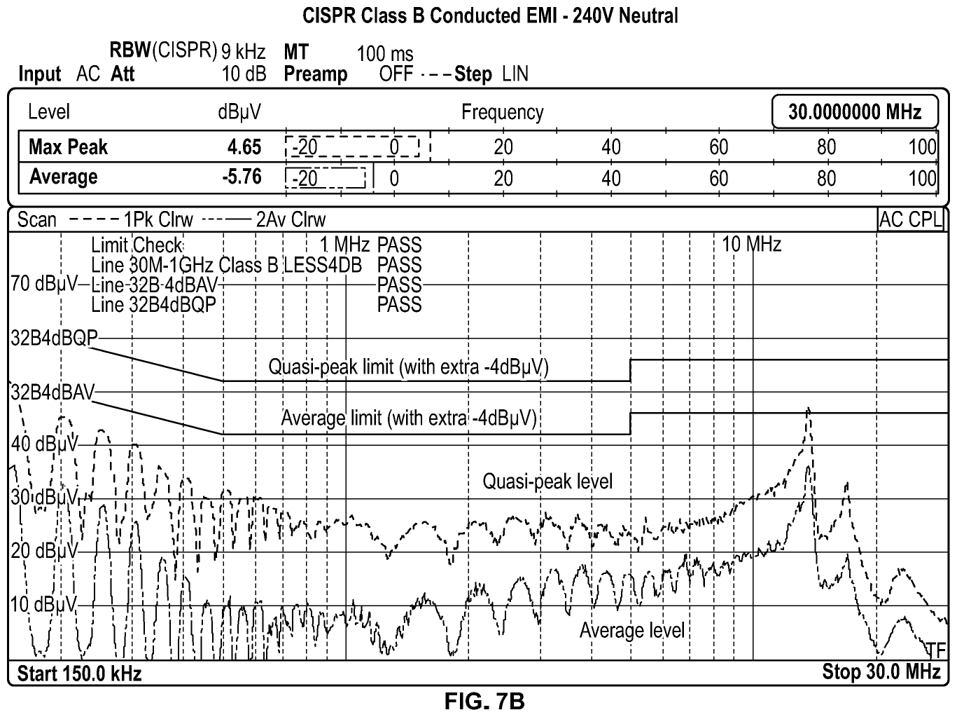

FIGS. 6A and 6B illustrate example line and neutral electromagnetic interference (EMI) test result scans of the transformer assembly 200 illustrated in FIG. 2B at 100 Volts (V). These test results are based on the International Special Committee on Radio Interference (CISPR) 22 regulations standard. Similarly, FIGS. 7A and 7B illustrate example line and neutral electromagnetic interference (EMI) test result scans of the transformer assembly 200 illustrated in FIG. 2B at 240 Volts (V).

FIGS. 6A-6B and 7A-7B show consistent EMI shielding by the electrically conductive shield 208 at multiple voltages up to thirty megahertz (MHz). In particular, the quasi-peak EMI voltage level and the average EMI voltage level in each case are below the quasi-peak limit and the average limit, over the range from 150 kilohertz (kHz) to 30 megahertz (MHz).

For example, as shown in FIGS. 6A-6B and 7A-7B, the CISPR Class B conducted EMI limit for a 0.15 to 0.50 MHz emission frequency slopes from 66 dBuV down to 56 dBuV for quasi-peak, and slopes from 56 dBuV down to 46 dBuV for average. In the 0.50-5.00 MHz emission frequency range the quasi-peak limit is 56 dBuV and the average limit is 46 dBuV, and in the 5.00-30.0 MHz emission frequency range the quasi-peak limit is 60 dBuV and the average limit is 50 dBuV.

As shown in FIGS. 6A-6B and 7A-7B, the EMI test result scans for the transformer assembly are under the required limits and comply with the standard for all tested levels. This consistent EMI shielding at all levels may be at least partially due to consistent production repeatability of wrapping the lead wire 210 around the electrically conductive shield 208. This may allow for a reduced cost due to higher efficiency and higher yield rate.

According to yet another example embodiment, a method of assembling a transformer including a magnetic transformer core is disclosed. The method includes winding a first wire about the magnetic transformer core to form at least one primary winding, winding a second wire about the magnetic transformer core to form at least one secondary winding, and wrapping an electrically conductive shield around at least a portion of the at least one primary winding and the at least one secondary winding to inhibit electromagnetic interference.

The electrically conductive shield includes an inner surface facing towards the at least one primary winding and the at least one secondary winding, and an outer surface facing away from the at least one primary winding and the at least one secondary winding.

The method also includes wrapping a lead wire around at least one of an outer surface of the electrically conductive shield, an outer surface (e.g. portion, etc.) of the at least one primary winding and an outer surface (e.g. portion, etc.) of the at least one secondary winding, to electrically couple the lead wire to the electrically conductive shield without solder and inhibit movement of the lead wire.

Wrapping the lead wire may include wrapping the lead wire at least 1.5 turns around the outer surface of the electrically conductive shield. Alternatively, the lead wire may be wrapped at least 1.5 turns around an outer surface of the at least one primary winding or around an outer surface of the at least one secondary winding, and wrapping the electrically conductive shield may include wrapping the electrically conductive shield around the at least 1.5 turns of the lead wire.

Wrapping the lead wire may include wrapping the lead wire using an automated winding machine. For example, wrapping the lead wire may include wrapping the lead wire using a multiple spindle automated winding machine.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A transformer assembly, comprising:
a magnetic transformer core;
at least one primary winding, the at least one primary winding wound about the magnetic transformer core;
at least one secondary winding, the at least one secondary winding wound about the magnetic transformer core;
an electrically conductive shield, the electrically conductive shield wrapped around the at least one primary winding and the at least one secondary winding to inhibit electromagnetic interference; and
a lead wire, the lead wire wrapped around at least a portion of the electrically conductive shield to mechanically and electrically couple the lead wire to the electrically conductive shield without solder.

2. The transformer assembly of claim 1, wherein:
the lead wire includes two wire ends;
the electrically conductive shield includes an outer surface;
a first one of the two wire ends extends beyond the electrically conductive shield at a first position on the outer surface of the electrically conductive shield; and
a second one of the two wire ends extends beyond the electrically conductive shield at a second position on the outer surface of the electrically conductive shield, the first position and second position located on opposite sides of the electrically conductive shield.

3. The transformer assembly of claim 1, wherein the lead wire comprises a tin-coated wire.

4. The transformer assembly of claim 1, wherein the electrically conductive shield comprises a belly band tape.

5. The transformer assembly of claim 4, wherein the electrically conductive shield comprises copper.

6. The transformer assembly of claim 1, further comprising a ground terminal electrically coupled with the at least one primary winding, wherein the lead wire is electrically coupled with the ground terminal.

7. The transformer assembly of claim 1, further comprising a voltage input terminal electrically coupled with the at least one primary winding, wherein the lead wire is electrically coupled with the voltage input terminal.

8. The transformer assembly of claim 1, further comprising at least one auxiliary winding wound about the magnetic transformer core, wherein the electrically conductive shield is wrapped around the at least one auxiliary winding to inhibit electromagnetic interference.

9. The transformer assembly of claim 1, wherein the at least one primary winding and the at least one secondary winding include a radial outer surface, and the electrically conductive shield is wrapped to cover at least fifty percent of the radial outer surface.

10. A switch-mode power supply comprising a power converter including the transformer assembly of claim 1.

11. The switch-mode power supply of claim 12, wherein the power converter comprises a flyback converter.

12. The transformer assembly of claim 1, wherein the lead wire is wrapped at least one and one half turns around the electrically conductive shield.

13. A method of assembling a transformer including a magnetic transformer core, the method comprising:
winding a first wire about the magnetic transformer core to form at least one primary winding;
winding a second wire about the magnetic transformer core to form at least one secondary winding;
wrapping an electrically conductive shield around the at least one primary winding and the at least one secondary winding to inhibit electromagnetic interference, the electrically conductive shield including an inner surface facing towards the at least one primary winding and the at least one secondary winding, and an outer surface facing away from the at least one primary winding and the at least one secondary winding; and
wrapping a lead wire around at least a portion of at least one of the outer surface of the electrically conductive shield, an outer surface of the at least one primary winding, and an outer surface of the at least one secondary winding, to electrically couple the lead wire to the electrically conductive shield without solder and inhibit movement of the lead wire.

14. The method of claim 13, wherein wrapping the lead wire includes wrapping the lead wire using an automated winding machine.

15. The method of claim 14, wherein the automated winding machine comprises a multiple spindle automated winding machine.

16. The method of claim 13, wherein wrapping the lead wire includes wrapping the lead wire at least one and one half turns around the outer surface of the at least one primary winding and/or around the outer surface of the at least one secondary winding, and wrapping the electrically conductive shield includes wrapping the electrically conductive shield around the at least one and one half turns of the lead wire.

17. The method of claim 13, wherein wrapping the lead wire includes wrapping the lead wire at least one and one half turns around the outer surface of the electrically conductive shield.

18. A transformer assembly, comprising:
a magnetic transformer core;
at least one primary winding, the at least one primary winding wound about the magnetic transformer core;
at least one secondary winding, the at least one secondary winding wound about the magnetic transformer core;
a lead wire, the lead wire wrapped around at least a portion of the at least one primary winding and the at least one secondary winding; and
an electrically conductive shield, the electrically conductive shield wrapped around the at least one primary winding and the at least one secondary winding to inhibit electromagnetic interference, and the electrically conductive shield wrapped over the lead wire to electrically couple the lead wire to the electrically conductive shield without solder and inhibit movement of the lead wire.

19. The transformer assembly of claim 18, wherein the lead wire comprises a tin-coated wire.

20. The transformer assembly of claim 18, wherein the lead wire is wrapped at least one and one half turns around the electrically conductive shield.

21-23. (canceled)
